(19) United States
(12) Patent Application Publication
(10) Pub. No.: US 2012/0211755 A1
(43) Pub. Date: Aug. 23, 2012

(54) THIN FILM TRANSISTOR, MANUFACTURING METHOD OF THIN FILM TRANSISTOR AND DISPLAY

(75) Inventors: Takashige Fujimori, Kanagawa (JP); Toshiaki Arai, Kanagawa (JP)

(73) Assignee: SONY CORPORATION, Tokyo (JP)

(21) Appl. No.: 13/365,780

(22) Filed: Feb. 3, 2012

(30) Foreign Application Priority Data
Feb. 17, 2011 (JP) 2011-032207

(51) Int. Cl. H01L 29/786; H01L 27/12; H01L 21/336

(52) U.S. Cl. 257/59; 438/158; 438/151; 257/347; 257/E27.112; 257/E21.409; 257/E29.273

(57) ABSTRACT

Disclosed herein is a manufacturing method of a thin film transistor including: forming a channel layer made of an oxide semiconductor above a gate electrode with a gate insulating film provided therebetween, forming a channel protection film made of a conductive material adapted to cover the channel layer and forming a pair of source and drain electrodes in such a manner as to be in contact with the channel protection film; and removing the region of the channel protection film between the source/drain electrodes by etching relying on selectivity between the conductive material and crystalline oxide semiconductor.

### CROSS REFERENCES TO RELATED APPLICATIONS

The present application claims priority to Japanese Priority Patent Application JP 2011-032207 filed in the Japan Patent Office on Feb. 17, 2011, the entire content of which is hereby incorporated by reference.

### BACKGROUND

The present disclosure relates to a thin film transistor (TFT) using an oxide semiconductor, a manufacturing method of the same and display having the same.

Oxide semiconductors including an oxide of zinc (Zn), indium (In), gallium (Ga), tin (Sn), aluminum (Al) or titanium (Ti), or an oxide of a mixture thereof are known to offer excellent semiconductor characteristics. Therefore, research efforts have been increasingly made in recent years to apply such semiconductors to TFTs for use as drive elements of active matrix displays. It has been found that if used as a TFT, oxide semiconductors have an electron mobility 10 times or greater than amorphous silicon TFTs commonly used in liquid crystal displays, and moreover offer favorable OFF characteristics. Further, oxide semiconductors are expected to have high mobility at low temperatures such as room temperature. Therefore, the application of such semiconductors to large-screen and high-definition liquid crystal displays and organic EL (Electro Luminescence) displays with high frame rate is much longed for.

As far as TFTs using an oxide semiconductor are concerned, those having a bottom gate structure and others having a top gate structure have been reported to date (e.g., Japanese Patent Laid-Open Nos. 2009-99944 and 2010-182929; Cetin Kilic and one other, “n-type doping of oxides by hydrogen,” Applied Physics Letters, Jul. 1, 2002, vol. 81, No 1, pp. 73-75; and Hsing-Hung Hsieh and 11 others, “A 2.4-in. AMOLED with IGZO TFTs and Inverted OLED Devices,” SID2010, 2010, 11.2, pp. 140-143). As an example of a known bottom gate structure, a gate electrode and gate insulating film are provided in this order from the substrate side, after which a thin film layer of an oxide semiconductor is formed in such a manner as to cover the top surface of the gate insulating film. This structure is similar to a bottom gate TFT structure using amorphous silicon as a channel that has reached commercial fruition. Therefore, a bottom gate structure often finds application in TFTs using an oxide semiconductor because of ease of diverting the existing TFT manufacturing process using amorphous silicon.

### SUMMARY

In such TFTs using an oxide semiconductor, there is a risk that TFT characteristics may degrade due to adherence of photoresist during the shaping of an oxide semiconductor, capable of serving as a channel, into an island form.

The present disclosure has been made in light of the foregoing, and it is desirable to provide a thin film transistor using an oxide semiconductor as its channel layer to offer excellent TFT characteristics, a manufacturing method of the same and a display having the same.

According to one mode of the present disclosure, there is provided a first manufacturing method of a thin film transistor. The method includes: forming a channel layer made of an oxide semiconductor above a gate electrode with a gate insulating film provided therebetween, forming a channel protection film made of a conductive material adapted to cover the channel layer and forming a pair of source and drain electrodes in such a manner as to be in contact with the channel protection film. The first manufacturing method also includes: removing the region of the channel protection film between the source/drain electrodes by etching relying on selectivity between the conductive material and crystalline oxide semiconductor.

According to another mode of the present disclosure, there is provided a second manufacturing method of a thin film transistor. The method includes: forming a channel layer made of an oxide semiconductor and a channel protection film made of a conductive material adapted to cover the channel layer. The second manufacturing method further includes: removing the channel protection film by etching relying on selectivity between the conductive material and crystalline oxide semiconductor. The second manufacturing method still further includes: forming a pair of source and drain electrodes above a channel layer in such a manner as to be in contact with a gate electrode and the channel layer with a gate insulating film provided therebetween.

In the manufacturing methods of a thin film transistor according to the above modes of the present disclosure, when an oxide semiconductor is shaped, that is, when a channel layer is formed by photolithography and etching steps, an oxide semiconductor film is covered with a conductive film (i.e., channel protection film), thus protecting the channel layer (oxide semiconductor film), for example, from adhesion of chemical substances caused by photoresist. Further, the channel layer is made of a crystalline oxide semiconductor, thus making selective etching between the channel layer and channel protection film easy in the channel protection film etching step.

According to a further mode of the present disclosure, there is provided a thin film transistor. The transistor includes a gate electrode, channel layer, a pair of channel protection films and a pair of source and drain electrodes. The channel layer is made of a crystalline oxide semiconductor and provided above the gate electrode with a gate insulating film provided therebetween. The pair of channel protection films are made of a conductive film, in contact with the channel layer and electrically disconnected from each other. Each of the pair of source and drain electrodes is electrically connected to the channel layer via one of the channel protection films.

Further, according to a still further mode of the present disclosure, there is provided a display. The display has the thin film transistor according to the above mode of the present disclosure as a pixel transistor so that each of the pixels is driven by the thin film transistor for image display.

In the thin film transistor, manufacturing method of the same and display having the same according to the modes of the present disclosure, when an oxide semiconductor is shaped into a channel layer, an oxide semiconductor film is covered with a conductive film (i.e., channel protection film), thus protecting the channel layer (oxide semiconductor film), for example, from chemical contamination caused by photoresist in the shaping step of the channel layer (oxide semiconductor film) and suppressing the degradation of the transfer characteristics of the thin film transistor. This makes it possible to manufacture a thin film transistor offering excellent TFT characteristics and improved reliability. Further, the channel layer is made of a crystalline oxide semiconductor, thus making selective etching between the channel layer and channel protection film easy.

Additional features and advantages are described herein, and will be apparent from the following Detailed Description and the figures.

### BRIEF DESCRIPTION OF THE FIGURES

FIG. 1 is a sectional view illustrating the structure of a thin film transistor according to a first embodiment of the present disclosure;

FIGS. 2A to 2F are sectional views illustrating the manufacturing method of the thin film transistor shown in FIG. 1 in the order of steps;

FIGS. 3A to 3C are sectional views illustrating, in the order of steps, the manufacturing method of when an oxide semiconductor film shown in FIG. 2C is made of an amorphous semiconductor;

FIGS. 4A and 4B are sectional views illustrating the structure of a thin film transistor according to comparative examples 1 and 2 in related art;

FIGS. 5A to 5C are diagrams illustrating the comparison in characteristics between the thin film transistor according to a working example shown in FIG. 1 and those according to the comparative examples;

FIGS. 6A to 6C are diagrams respectively illustrating partially enlarged views of FIGS. 5A to 5C;

FIG. 7 is another diagram illustrating the comparison in characteristics between the thin film transistor according to the working example shown in FIG. 1 and those according to the comparative examples;

FIG. 8 is a sectional view illustrating the structure of a thin film transistor according to a modification example;

FIG. 9 is a sectional view of a thin film transistor whose source and drain electrodes have a common multilayer structure;

FIGS. 10A to 10F are sectional views illustrating, in the order of steps, the manufacturing method of the thin film transistor according to a second embodiment of the present disclosure;

FIG. 11 is a diagram illustrating the circuit configuration of a display according to application example 1;

FIG. 12 is an equivalent circuit diagram illustrating an example of a pixel drive circuit shown in FIG. 11;

FIG. 13 is a perspective view illustrating the appearance of application example 2;

FIG. 14A is a perspective view illustrating the appearance of application example 3 as seen from the front, and FIG. 14B is a perspective view illustrating the appearance thereof as seen from the back;

FIG. 15 is a perspective view illustrating the appearance of application example 4;

FIG. 16 is a perspective view illustrating the appearance of application example 5; and

FIG. 17A is a front view of application example 6 in an open position, FIG. 17B is a side view thereof, FIG. 17C is a front view in a closed position, FIG. 17D is a left side view, FIG. 17E is a right side view, FIG. 17F is a top view, and FIG. 17G is a bottom view.

### DETAILED DESCRIPTION

A detailed description will be given below of the preferred embodiments of the present disclosure with reference to the accompanying drawings. It should be noted that the description will be given in the following order.

1. First embodiment (example of a bottom gate thin film transistor)
2. Modification example (bottom gate thin film transistor; example in which the channel protection layer makes up one of the layers of the source/drain electrodes)
3. Second embodiment (example of a top gate thin film transistor)

### First Embodiment

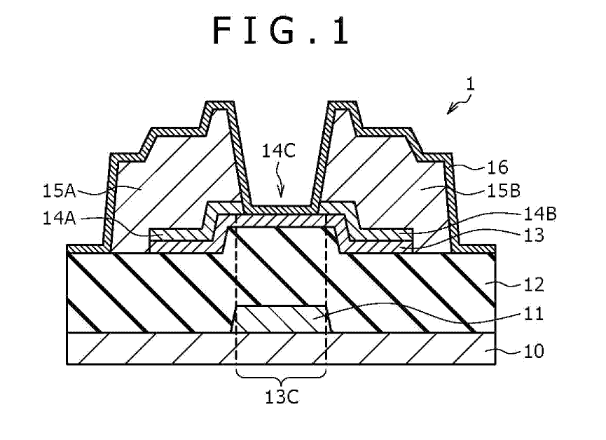

FIG. 1 illustrates the sectional structure of a bottom gate (reverse-staggered) thin film transistor 1 according to a first embodiment of the present disclosure. The thin film transistor 1 is used as a drive element of displays such as liquid crystal and organic EL displays. The same transistor 1 includes, for example, a gate electrode 11, gate insulating film 12 and channel layer 13 made of a crystalline oxide semiconductor stacked in this order on a substrate 10. Channel protection films 14A and 14B are provided on the channel layer 13. Source/drain electrodes 15A and 15B are connected to the channel layer 13 respectively via the channel protection films 14A and 14B. A protection film 16 is formed on the source/drain electrodes 15A and 15B to cover the entire area above the substrate 10.

The substrate 10 is made of a glass substrate, plastic film or other material. Among plastic materials that can be used are PET (polyethylene terephthalate) and PEN (polyethylene naphthalate). In the thin film transistor 1 according to the present embodiment, the channel layer 13 is formed by sputtering (described later) without heating the substrate 10. As a result, inexpensive plastic film can be used.

The gate electrode 11 plays a role of controlling the carrier density in the channel layer 13 by using a gate voltage applied to the thin film transistor 1. Provided at a selective region on the substrate 10, the gate electrode 11 is 10 nm to 500 nm in thickness and made of a metal such as platinum (Pt), titanium (Ti), ruthenium (Ru), molybdenum (Mo), copper (Cu), tungsten (W), nickel (Ni), aluminum (Al) or tantalum (Ta) or an alloy thereof.

The gate insulating film 12 is 50 nm to 1 μm in thickness and made of an insulating film including at least one of a silicon oxide film, silicon nitride film, silicon oxynitride film, hafnium oxide film, aluminum oxide film, tantalum oxide film, zirconium oxide film, hafnium oxynitride film, aluminum oxynitride film, tantalum oxynitride film and zirconium oxynitride film. The gate insulating film 12 may have a single layer structure or multilayer structure made up of two or more layers of different types. If the gate insulating film 12 has a multilayer structure made up of two or more layers of different types, it is possible to improve the characteristics of the interface with the channel layer 13 or prevent impurities being mixed in the channel layer 13 from outside air.

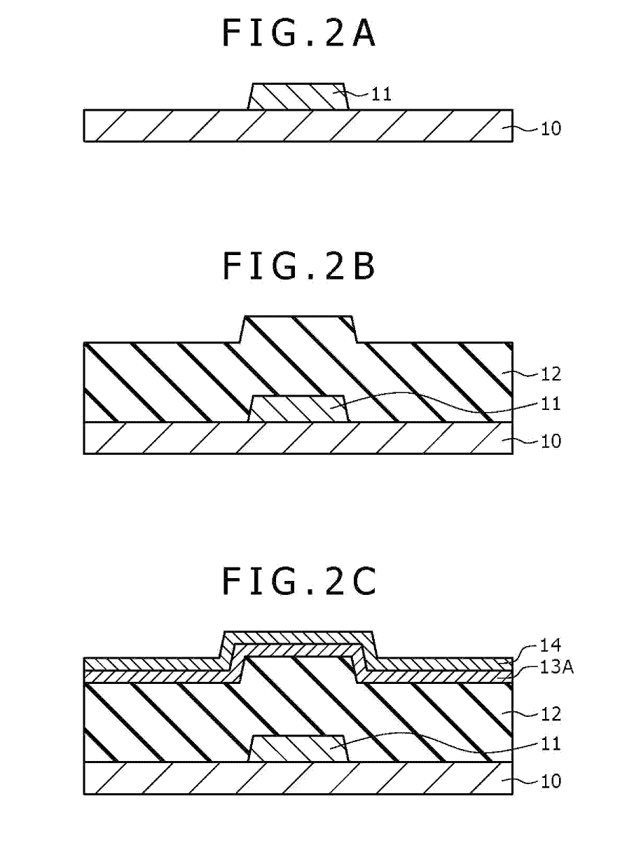

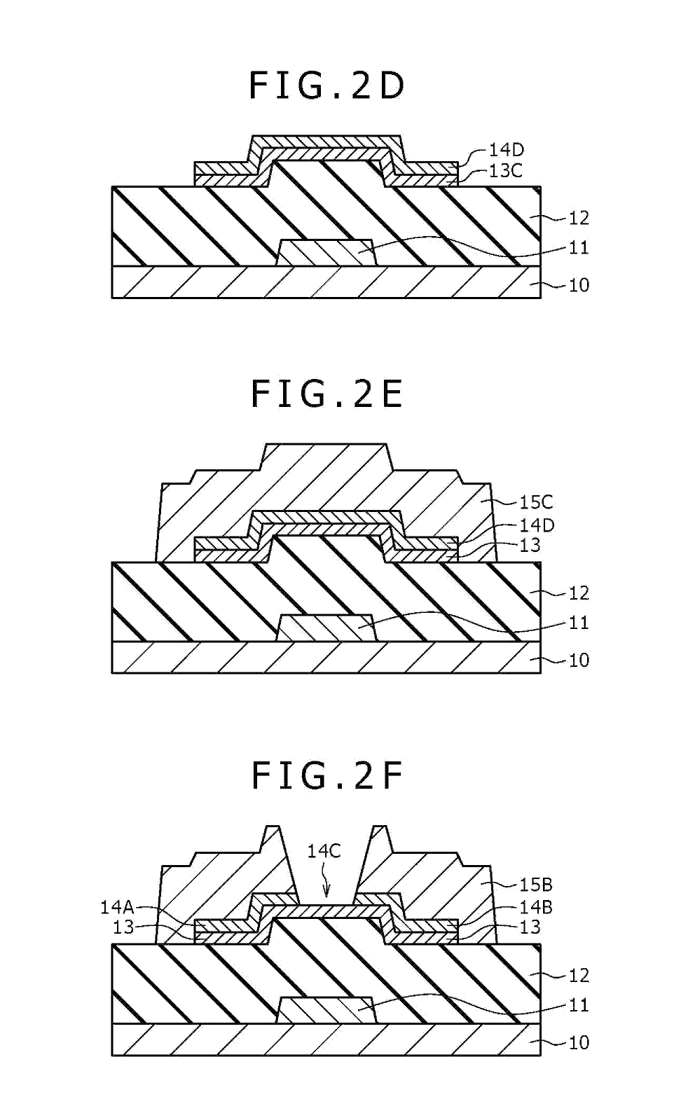

The channel layer 13 made of a crystalline oxide semiconductor is provided in an island shape on the gate insulating film 12, and a channel region 13C is formed at a position between the source/drain electrodes 15A and 15B opposed to the gate electrode 11. The channel layer 13 is formed by shaping an oxide semiconductor film 13A (FIG. 2C) as will be described later and contains, as the main ingredient, an oxide of at least one of the elements including indium, gallium, zinc, tin, aluminum and titanium. The channel layer 13 is, for example, made of IGO (Indium-Gallium-Oxide), IZO (Indium-Zinc-Oxide), ITO (Indium-Tin-Oxide) or ZnO (Zinc-Oxide) and is about 20 nm to 100 nm in thickness.

The channel protection films 14A and 14B are provided respectively between the source/drain electrode 15A and channel layer 13 and between the source/drain electrode 15B and channel layer 13. The same films 14A and 14B are formed by shaping a conductive film 14 (FIG. 2C). Further, a gap 14C is provided between the channel protection films 14A and 14B on the channel region 13C so that the same films 14A and 14B are electrically disconnected from each other. That is, the source/drain electrodes 15A and 15B are electrically connected to the channel layer 13 respectively via the channel protection films 14A and 14B.

The channel protection films 14A and 14B should preferably be made, for example, of molybdenum, titanium, manganese (Mn) or copper, or a conductive material that is made of an oxide, nitride or oxynitride thereof. Molybdenum, titanium, manganese and copper exhibit excellent adhesion to the channel layer 13. This contributes to reduced contact resistance between the source/drain electrodes 15A and 15B and channel layer 13 and provides a wider range of selection of metals for use as the source/drain electrodes 15A and 15B.

Even if an amorphous oxide semiconductor material is used for the channel protection films 14A and 14B, selective etching is also possible between the same films 14A and 14B and the channel layer 13 made of a crystalline oxide semiconductor. The channel protection films 14A and 14B made of such an amorphous oxide semiconductor material are, for example, similar in thickness, i.e., 20 nm to 100 nm or more in thickness.

The source/drain electrodes 15A and 15B are each a single layer film made, for example, of molybdenum, aluminum, copper, titanium or ITO (indium-tin oxide) or an alloy thereof, or a multilayer film made up of two or more layers of different types. If, for example, the source/drain electrodes 15A and 15B are each a three-layer film formed by stacking a 50 nm molybdenum film, a 1 μm aluminum film and a 50 nm molybdenum film in this order, it is possible to stably maintain the electrical characteristics of the channel layer 13.

The protection film 16 includes a thin film made, for example, of an aluminum oxide film, aluminum oxynitride film, silicon oxide film, silicon nitride film, titanium oxide film or titanium oxynitride film. The same film 16 has the capability to suppress the change in electrical characteristics of the channel layer 13 caused, for example, by adsorption of moisture or penetration of oxygen, thus stabilizing the electrical characteristics of the thin film transistor 1.

The thin film transistor 1 can be manufactured, for example, in the following manner.

FIGS. 2A to 2F illustrate the manufacturing method of the thin film transistor 1 in the order of the steps. First, a metal film adapted to serve as the gate electrode 11 is formed over the entire surface of the substrate 10, for example, by sputtering or CVD (Chemical Vapor Deposition). Next, the metal film formed on the substrate 10 is patterned, for example, by photolithography or etching as illustrated in FIG. 2A, thus forming the gate electrode 11.

Next, the gate insulating film 12 made of a silicon nitride or silicon oxide film is formed over the entire surfaces of the substrate 10 and gate electrode 11, for example, by sputtering or CVD, as illustrated in FIG. 2B.

More specifically, a silicon nitride film is formed by plasma CVD using gases such as silane, ammonium and nitrogen as source gases, and a silicon oxide film is formed by plasma CVD using gases including silane and nitrous oxide as source gases.

After forming the gate insulating film 12, the oxide semiconductor film 13A made of a material making up the channel layer 13 (FIG. 1) and the conductive film 14 made of a material making up the channel protection films 14A and 14B (FIG. 1) are formed in this order as illustrated in FIG. 2C.

For example, if the oxide semiconductor film 13A is made of a semiconductor material containing primarily indium oxide and also zinc and gallium, the same film 13A is formed in the following manner. That is, the oxide semiconductor film 13A is formed on the substrate 10 and gate insulating film 12 not only by DC (Direct Current), RF (Radio Frequency) or AC (Alternating Current) sputtering using ceramics of indium-zinc oxide or indium-gallium oxide as a target but also by means of plasma discharge using a mixture gas of argon (Ar) and oxygen (O₂). It should be noted that argon and oxygen gases are introduced into the vacuum chamber after evacuating the chamber until a vacuum level of 1×10⁻⁴ Pa or less is reached prior to plasma discharge. At this time, it is possible to control the composition of the metal elements in the oxide semiconductor material and the crystallinity of the same material by varying at least one of the DC, RF or AC power, the oxygen or vapor concentration in argon and the back pressure during sputtering.

Next, the conductive film 14 made, for example, of molybdenum is formed by sputtering. The same film 14 can be readily formed as described above by the same method as for the oxide semiconductor film 13A.

Next, the conductive film 14 and oxide semiconductor film 13A are shaped into an island form so as to include the area opposed to the gate electrode 11 and vicinity to the electrode 11, for example, by photolithography or etching as illustrated in FIG. 2D. If the oxide semiconductor film 13A made of a crystalline oxide semiconductor is formed, the channel layer 13 covered with a channel protection film 14D is formed. In the present embodiment, the conductive film 14 and oxide semiconductor film 13A are formed at the same time. Therefore, the channel layer 13 and channel protection film 14D are formed into the same shape except that they differ in thickness, that is, their edge portions are formed at the same positions. At this time, the oxide semiconductor film 13A (channel layer 13) is covered with the conductive film 14 (channel protection film 14D), thus protecting the same film 13A, for example, from adhesion of chemical substances caused by photoresist.

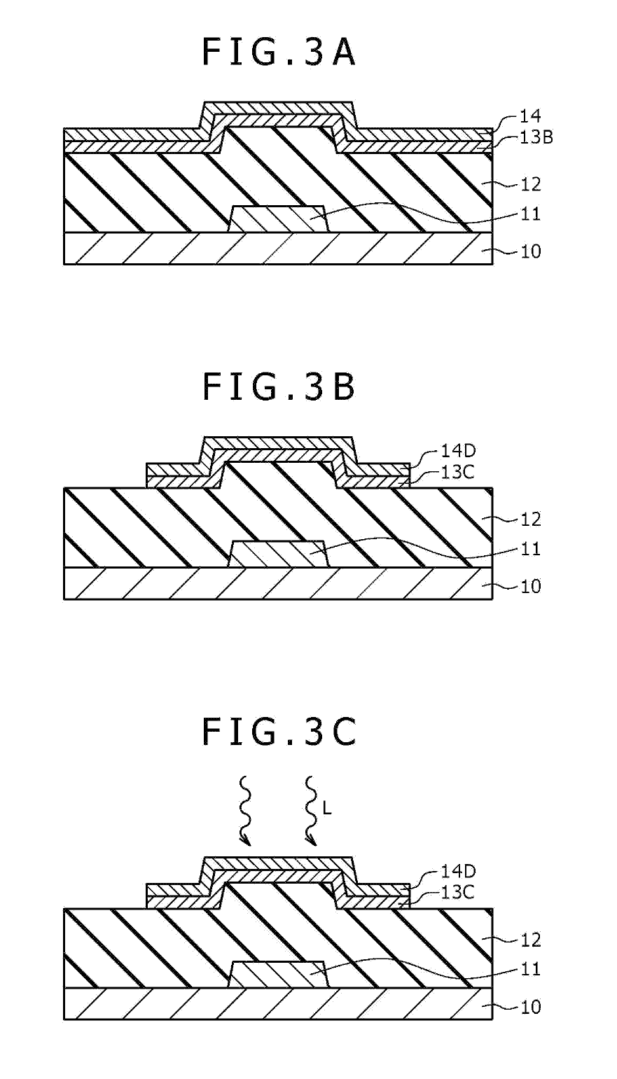

An amorphous oxide semiconductor film 13B may be formed as illustrated in FIG. 3A rather than the crystalline oxide semiconductor film 13A illustrated in FIG. 2C. The amorphous oxide semiconductor film 13B is lower in etching resistance than the crystalline oxide semiconductor film 13A, making the selection of an etching method easy for forming the conductive film 14 and amorphous oxide semiconductor film 13B (FIG. 3B). After shaping the conductive film 14 and amorphous oxide semiconductor film 13B respectively into the channel protection film 14D and oxide semiconductor film 13C, the amorphous oxide semiconductor is transformed into a crystalline oxide semiconductor, that is, a phase change is made (FIG. 3C), by thermal treatment such as irradiation of a laser beam L, heating with a heater or heating with an atmospheric gas. The amorphous oxide semiconductor should preferably be transformed into a crystalline oxide semiconductor prior to the formation of a metal film (FIG. 2E) which will be described later. The reason for this is that it is possible to prevent the deterioration of the metal film 15C caused by thermal treatment adapted to achieve the phase change. The channel layer 13 is formed as a result of the phase change from the amorphous oxide semiconductor into the crystalline oxide semiconductor (FIG. 2D). On the other hand, if the crystalline oxide semiconductor film 13A is formed, a step for such a phase change is not necessary, thus contributing to a reduced number of steps.

Next, as illustrated in FIG. 2E, a titanium layer of about 50 nm in thickness, an aluminum or copper layer of about 1 μm in thickness and a titanium layer of about 50 nm in thickness are formed in this order, for example, by sputtering, thus forming the metal film 15C having a three-layer structure. Titanium and an oxide semiconductor material together produce a titanium oxide (TiOₓ). As a result, it is difficult to form a titanium layer in contact with the channel layer made of an oxide semiconductor material. Aluminum and copper also have problems with the channel layer, namely, diffusion into the channel layer and etching selectivity problem. The channel protection film 14D resolves all these problems, thus making the selection of a metal material usable for the source/drain electrodes easy. The oxide semiconductor layer may be changed in phase from an amorphous state to a crystalline state after the formation of the metal film 15C.

After forming the metal film 15C, the same film 15C is patterned, for example, by wet etching using PAN (Phosphoric-Acetic-Nitric-acid; mixture solution containing phosphoric, acetic and nitric acids and water)-based chemical solution as illustrated in FIG. 2F, thus forming the pair of source/drain electrodes 15A and 15B. Fluoric acid or hydrochloric acid may be used as a chemical solution during wet etching if the channel layer 13 is made, for example, of a material resistant to fluoric acid or hydrochloric acid.

The gap 14C shown in FIG. 1 is formed in the channel protection film 14D simultaneously with the formation of the source/drain electrodes 15A and 15B or in a separate step using the photoresist, used during the formation of the source/drain electrodes 15A and 15B, as an etching mask. This is intended to prevent electrical connection between the source/drain electrodes 15A and 15B via the channel protection film 14D. This step forms the channel protection films 14A and 14B respectively between the source/drain electrode 15A and channel layer 13 and between the source/drain electrode 15B and channel layer 13. If the gap 14C is formed as described above, the opposed surfaces of the channel protection films 14A and 14B are aligned with those of the pair of source/drain electrodes 15A and 15B. That is, the respective opposed surfaces form the same surfaces.

In the thin film transistor 1, the channel layer 13 is made of a crystalline oxide semiconductor highly resistant to etching. This provides a wider range of selection of etching methods in the step of providing the channel protection film 14D and gap 14C than when the channel layer 13 is made of an amorphous oxide semiconductor film, thus making selective etching between the channel layer and channel protection film easy.

If the channel protection film 14D is made, for example, of molybdenum, an oxidation treatment following the formation of the source/drain electrodes 15A and 15B transforms the channel protection film 14D between the source/drain electrodes 15A and 15B into a molybdenum oxide. The same film 14D is rinsed with water at room temperature or warm water or with an organic amine-based chemical solution, thus forming the gap 14C and channel protection films 14A and 14B. On the other hand, if the channel layer 13 is made of an oxide semiconductor material resistant to PAN, fluoric acid or hydrochloric acid, the channel protection layer 14D is formed with a material soluble in PAN, fluoric acid or hydrochloric acid, thus making it possible to form the gap 14C and channel protection films 14A and 14B by wet etching using PAN, fluoric acid or hydrochloric acid. For example, among PAN-soluble materials that can be used as the channel protection layer 14D are molybdenum, aluminum and copper. Among fluoric-acid-soluble materials that can be used as the channel protection layer 14D are titanium and aluminum. Among hydrochloric-acid-soluble materials that can be used as the channel protection layer 14D is ITO. If the channel protection layer 14D is made of an oxide semiconductor material, the gap 14C and channel protection films 14A and 14B can be formed in the same manner. Wet etching may be performed simultaneously with the formation of the source/drain electrodes 15A and 15B. Alternatively, wet etching may be performed following the formation of the source/drain electrodes 15A and 15B using the photoresist, used during the formation of the same electrodes 15A and 15B, as an etching mask. In either case, no lithography step is added thanks to the fact that the channel protection film 14D (conductive film 14) is stacked.

As described above, the conductive film 14 is formed on the oxide semiconductor films 13A and 13B in the present embodiment, thus protecting the channel layer 13, for example, from adhesion of chemical substances. Further, the channel layer 13 is made of a crystalline oxide semiconductor, thus making selective etching between the channel layer 13 and channel protection film 14D easy when the channel protection film 14D is electrically disconnected between the source/drain electrodes 15A and 15B.

On the other hand, if the oxide semiconductor film 13B made of an amorphous oxide semiconductor is formed and transformed from an amorphous oxide semiconductor into a crystalline oxide semiconductor in a later step, the oxide semiconductor film 13B and conductive film 14 can be etched with more ease than when the oxide semiconductor film 13A made of a crystalline oxide semiconductor is formed.

Further, the gap 14C can be formed in the channel protection film 14D without adding any new lithography step. Moreover, if the gap 14C is formed simultaneously with the formation of the source/drain electrodes 15A and 15B, the thin film transistor 1 can be manufactured without adding any etching step. That is, it is possible to prevent the degradation of the transfer characteristics by a simple method that allows easy film formation and eliminates the need for any special patterning.

After forming the source/drain electrodes 15A and 15B, the protection film 16 made of the above described materials is formed, for example, by plasma CVD or sputtering, thus completing the thin film transistor 1 shown in FIG. 1.

When a voltage equal to or greater than the threshold voltage of the gate electrode 11 is applied via a wiring layer not shown to the same electrode 11 in the thin film transistor 1, a current (drain current) is generated in the channel region 13C of the channel layer 13. In the present embodiment, the oxide semiconductor film 13A (channel layer 13) is covered with the channel protection film 14D (conductive film 14), thus suppressing the degradation of the transfer characteristics of the thin film transistor. Further, the channel layer 13 is made of a crystalline oxide semiconductor, thus allowing for selective etching between the channel layer and channel protection film with ease in the step of forming the gap 14C in the channel protection film 14D.

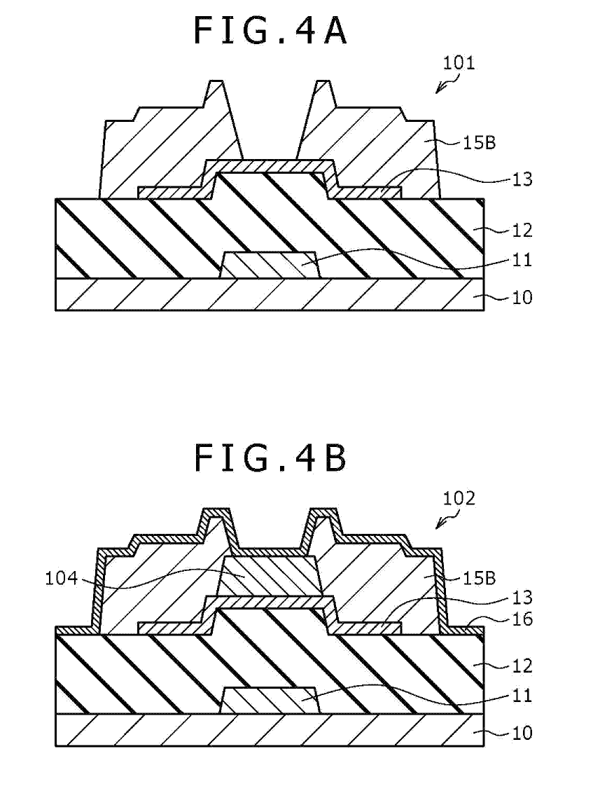

Here, it is shown by way of comparative examples that the channel protection film suppresses the degradation of the transfer characteristics of the thin film transistor. FIG. 4A illustrates the sectional structure of a thin film transistor 101 having a back-channel-etched structure according to comparative example 1. On the other hand, FIG. 4B illustrates the sectional structure of a thin film transistor 102 having an etch stopper structure according to comparative example 2.

The thin film transistor 101 according to comparative example 1 includes the gate electrode 11, gate insulating film 12, channel layer 13 and source/drain electrodes 15A and 15B stacked on the substrate 10. The same transistor 101 differs from the thin film transistor 1 according to the present embodiment in that the channel protection films 14A and 14B are not provided. It has been reported that photoresist may adhere to the channel layer 13 and degrade the TFT characteristics when an oxide semiconductor film is shaped into an island form to form the same layer 13 in the thin film transistor 101.

On the other hand, the thin film transistor 102 according to comparative example 2 has an etch stopper layer 104 provided on the channel layer 13 of the thin film transistor 101. The etch stopper layer 104 suppresses the degradation of the characteristics when the channel layer 13 is formed. However, a larger number of steps are necessary for the thin film transistor 102 than for the thin film transistor 101 because of the film formation, photolithography and etching steps adapted to form the etch stopper layer 104.

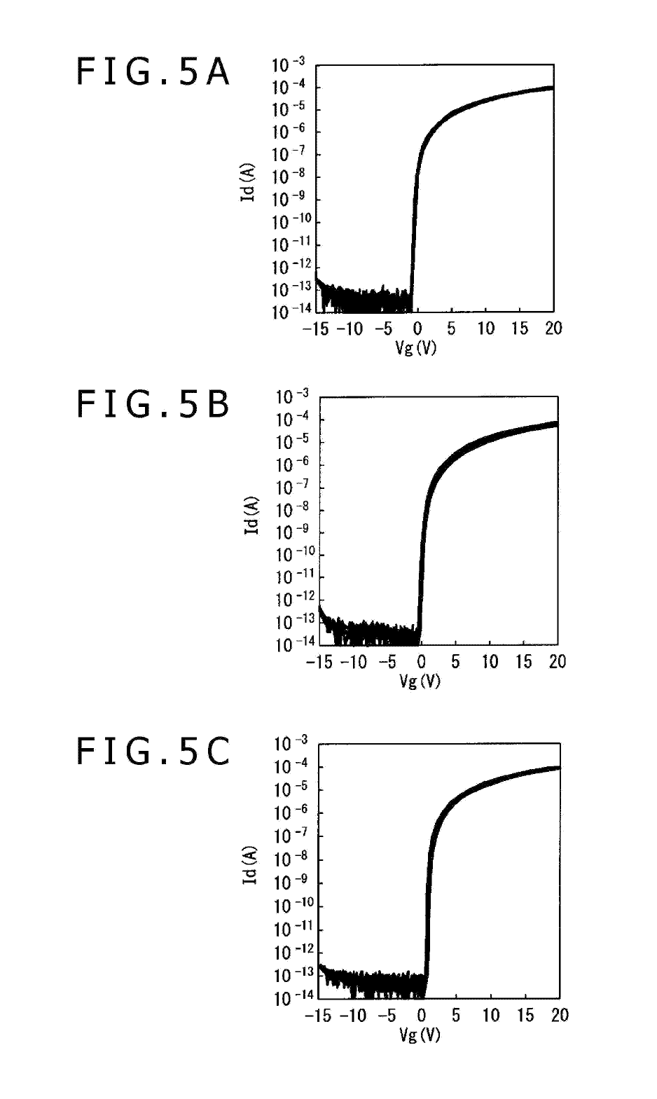

FIG. 5A illustrates the study results of the transfer characteristics of the thin film transistor 1 obtained by practically manufacturing, as a working example, the same transistor 1 having the channel protection films 14A and 14B by the manufacturing method described above. At this time, a molybdenum film of 50 nm in thickness was used as the channel protection films 14A and 14B. It should be noted that it has been confirmed that similar results can be obtained when the molybdenum film is 10 nm in thickness.

In contrast, FIGS. 5B and 5C illustrate the study results of the transfer characteristics of the thin film transistors 101 and 102 respectively according to comparative examples 1 and 2.

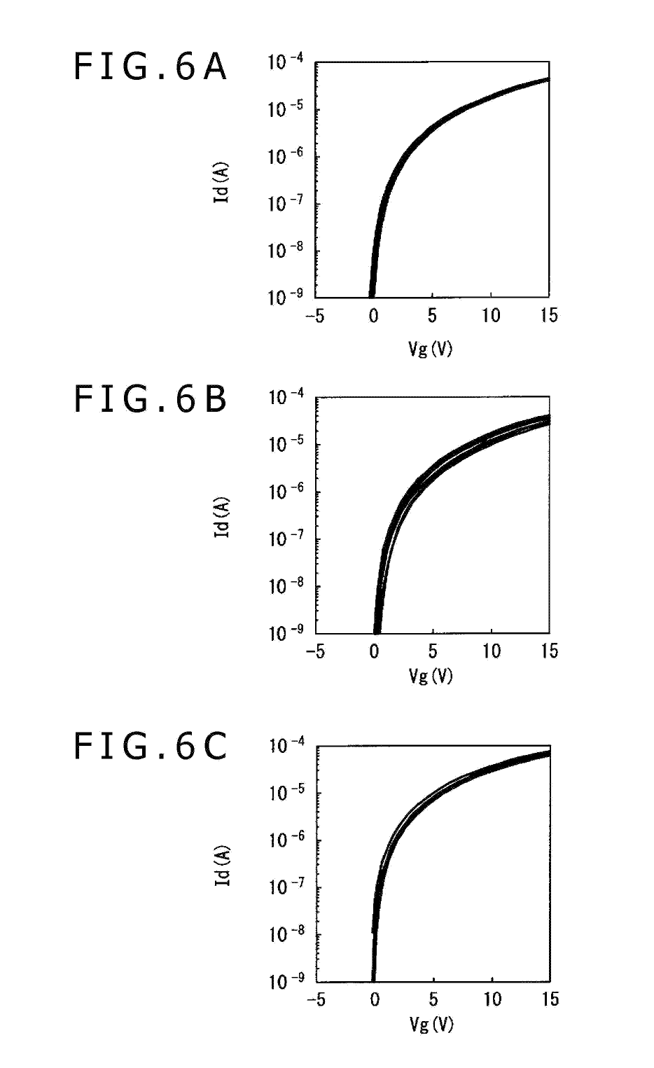

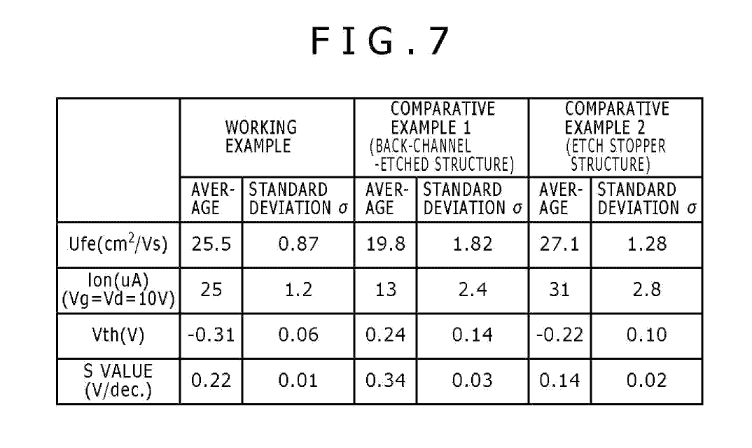

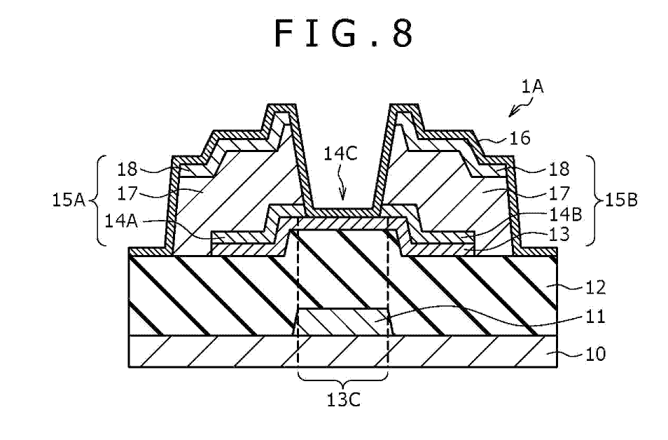

FIGS. 6A to 6C illustrate partially enlarged views of FIGS. 5A to 5C, respectively. FIG. 7 illustrates TFT characteristic parameters of the working example and comparative examples 1 and 2. In FIG. 7, Ufe is the mobility, Ion the ON output current, Vth the threshold voltage, and S value the subthreshold factor.

As is clear from FIGS. 6A to 6C, the transfer characteristics of comparative example 1 vary more than those of the working example and comparative example 2. In contrast, the transfer characteristics are maintained more or less constant in the working example and comparative example 2.

When we focus our attention on Ufe (cm²/Vs) representing the mobility in FIG. 7, the Ufe value is significantly smaller in comparative example 1 than in comparative example 2. On the other hand, the Ufe value in the working example is maintained at a similar level to that of comparative example 2. Further, a standard deviation σ is smaller in the working example than in comparative example 2. That is, it is clear that the variation across the substrate is small. Therefore, it has been found from these results that the degradation of the TFT characteristics (field effect mobility and variation thereof across the substrate) of the thin film transistor 1 is suppressed by a simple method without adding a lithography step.

On the other hand, the size of the thin film transistor 102 having an etch stopper structure is determined by the size of the etch stopper layer 104, making it difficult to downsize the transistor. In contrast, the thin film transistor 1 can be downsized, thus contributing to reduced parasitic capacitance.

In the present embodiment as described above, when the oxide semiconductor films 13A and 13B are shaped into the channel layer 13, the same films 13A and 13B are covered with the conductive film 14 (channel protection film 14D), thus ensuring that the channel layer 13 (oxide semiconductor films 13A and 13B) is free from adhesion of chemical substances caused by photoresist. This suppresses the degradation of the transfer characteristics of the obtained thin film transistor 1, thus providing uniform and excellent TFT characteristics and contributing to improved reliability.

Further, the channel layer is made of a crystalline oxide semiconductor in the present embodiment, thus making selective etching between the channel layer and channel protection film easy.

### Modification Example

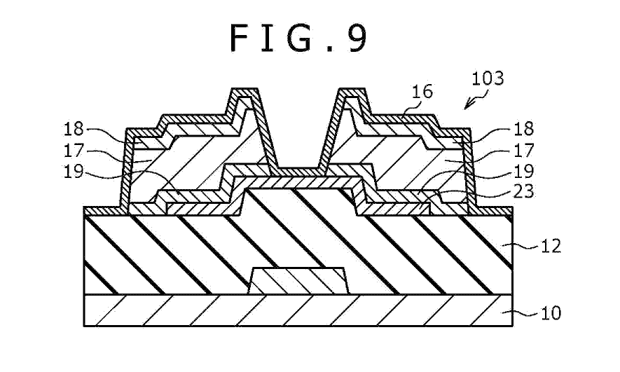

FIG. 8 illustrates the sectional structure of a thin film transistor 1A according to a modification example of the present disclosure. The source/drain electrodes 15A and 15B of the thin film transistor 1A have a multilayer structure, with the channel protection films 14A and 14B making up the closest of all the layers of the multilayer structure to the channel layer 13. Metal films 17 and 18 are stacked on the channel protection films 14A and 14B. That is, the source/drain electrode 15A has a three-layer structure made up of the channel protection film 14A, and metal films 17 and 18, and the source/drain electrode 15B a three-layer structure made up of the channel protection film 14B, and metal films 17 and 18.

It is common for the source/drain electrodes of bottom gate thin film transistors to have a multilayer structure. FIG. 9 illustrates the sectional structure of a common thin film transistor 103 whose source and drain electrodes have a multilayer structure. A metal film 19 closest to a semiconductor layer 23 suppresses the diffusion of the metal to the semiconductor layer 23 or stabilizes the electrical contact with the same layer 23. On the other hand, a metal film 18 farthest from the semiconductor layer 23 suppresses the thermal migration of a metal film 17 provided between the metal films 19 and 18 or stabilizes the electrical contact with the conductive layer to be joined. Among combinations of metals used for such a multilayer structure are a molybdenum/aluminum/molybdenum combination and a titanium/aluminum/titanium combination.

In the thin film transistor 1A, the channel protection films 14A and 14B make up one of the layers of the source/drain electrodes 15A and 15B, thus making it possible to manufacture a thin film transistor offering excellent transfer characteristics without adding not only lithography and etching steps but also a film formation step. Except in this respect, the thin film transistor 1A is identical in structure to the thin film transistor 1 according to the first embodiment and provides the same action and effect as the same transistor 1.

The thin film transistor 1A can be manufactured, for example, in the following manner. First, the gate electrode 11, gate insulating film 12, channel layer 13 and channel protection film 14D are formed on the substrate 10 by following the steps shown from FIG. 2A to FIG. 2D as in the first embodiment. For example, the channel protection film 14D is formed with molybdenum. Next, an aluminum layer and a molybdenum layer, for example, are formed on the channel protection film 14D, followed by simultaneous etching of the channel protection film 14D, aluminum layer and molybdenum layer. This forms the source/drain electrodes 15A and 15B, each made up of one of the channel protection films 14A and 14B, the metal film 17 made of aluminum and the metal film 18 made of molybdenum. Finally, the protection film 16 is provided as in the first embodiment, thus completing the thin film transistor 1A.

The conductive film 14 is stacked on the oxide semiconductor film 13A in the thin film transistor 1A. However, the conductive film 14 makes up one of the layers of the source/drain electrodes 15 in a later step. This makes it possible to manufacture the thin film transistor 1A without increasing the number of times the films are formed. On the other hand, the oxide semiconductor film and source and drain electrodes are commonly formed by sputtering. In the thin film transistor 1A, therefore, the oxide semiconductor film 13A and conductive film 14 can be formed by continuous sputtering.

### Second Embodiment

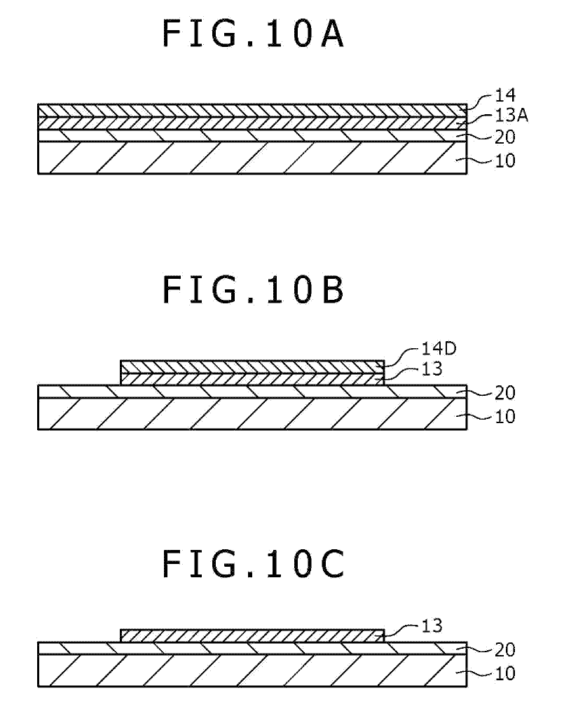

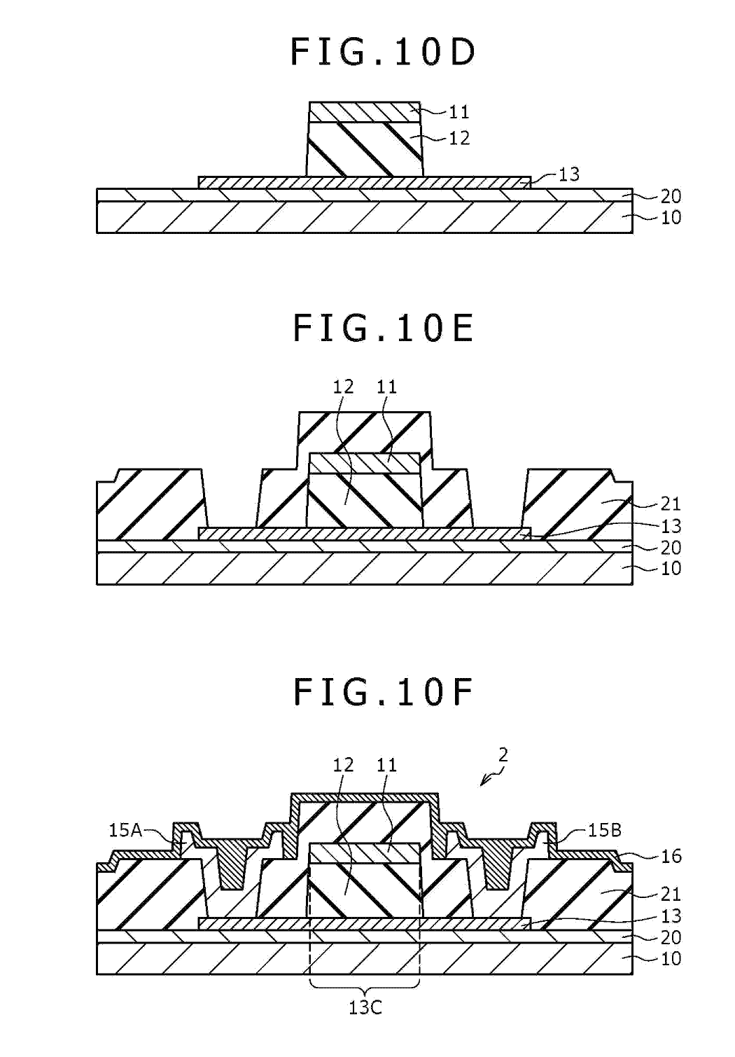

FIGS. 10A to 10F illustrate the manufacturing method of a top gate (staggered) thin film transistor 2 according to a second embodiment of the present disclosure. The thin film transistor 2 includes the channel layer 13, gate insulating film 12, gate electrode 11, an interlayer insulating film 21 and the source/drain electrodes 15A and 15B stacked in this order above the substrate 10 having a buffer layer 20. The channel layer 13 has the channel region 13C opposed to the gate electrode 11. It should be noted that although differing in arrangement of the components from the counterpart according to the first embodiment, the thin film transistor 2 has the same functionality and is made of the same materials as the counterpart according to the first embodiment. Therefore, the components are denoted by the same reference numerals, and the description thereof is omitted as appropriate.

A description will be given next of the manufacturing method of the thin film transistor 2 with reference to FIGS. 10A to 10F.

As illustrated in FIG. 10A, the oxide semiconductor film 13A and conductive film 14 are formed in this order above the substrate 10 having the buffer layer 20 made of a silicon oxide or silicon nitride film. The oxide semiconductor film 13A is made of a material making up the channel layer 13, and the conductive film 14 is made of a conductive material.

Next, the conductive film 14 and oxide semiconductor film 13A are shaped into an island form, for example, by photolithography or etching as illustrated in FIG. 10B. This forms the channel layer 13 covered with the channel protection film 14D. The amorphous oxide semiconductor film 13B (not shown) may be formed as described in FIGS. 3A to 3C rather than the oxide semiconductor film 13A. After etching the conductive film 14 and oxide semiconductor film 13B and prior to the removal of the channel protection film 14D (FIG. 10C), the amorphous oxide semiconductor should preferably be transformed into a crystalline oxide semiconductor so as to form the channel layer 13.

After forming the channel layer 13, the channel protection film 14D is removed as illustrated in FIG. 10C.

After removing the channel protection film 14D, two films, one made of a gate insulating material and another made of a gate electrode material, are formed over the entire surfaces of the substrate 10 and channel layer 13, for example, by plasma CVD or sputtering, followed by shaping of the gate electrode material film, for example, by photolithography or etching, thus forming the gate electrode 11 above the channel region 13C of the channel layer 13. Next, the gate insulating material film is etched using the gate electrode 11 as a mask, thus forming the gate insulating film 12. This forms the gate insulating film 12 and gate electrode 11 in this order on the channel region 13C of the channel layer 13 as illustrated in FIG. 10D. It should be noted that the gate insulating film 12 and gate electrode 11 are formed in the same shape but with different thicknesses.

Next, the interlayer insulating film 21 made, for example, of an organic insulating film such as polyimide, silicon oxide film or silicon nitride film, is formed over the entire surfaces of the gate electrode 11 and channel layer 13, after which a connection hole is provided in the same film 21 as illustrated in FIG. 10E. The protection film 16 may be used rather than the interlayer insulating film 21. Alternatively, the protection film 16 may be provided on top of or under the interlayer insulating film 21.

After providing the connection hole in the interlayer insulating film 21, the source/drain electrodes 15A and 15B and protection film 16 are formed in the same manner as in the first embodiment. If the protection film 16 is used rather than the interlayer insulating film 21, the protection film 16 on the source/drain electrodes 15A and 15B may be omitted. This completes the top gate thin film transistor 2 illustrated in FIG. 10F.

The thin film transistor 2 offers the same action and effect as the counterpart according to the first embodiment.

### Application Example 1

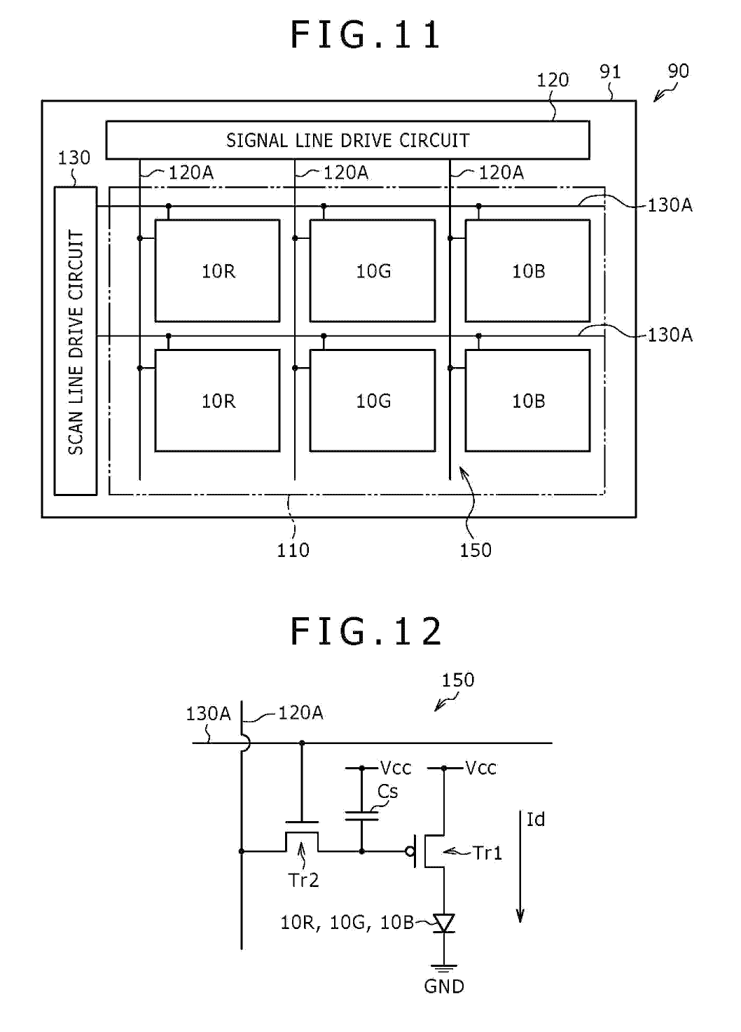

FIG. 11 illustrates the circuit configuration of a display having, as a drive element, one of the thin film transistors 1, 1A and 2. A display 90 is, for example, a liquid crystal or organic EL display that has a plurality of pixels 10R, 10G and 10B, arranged in a matrix form, and various drive circuits adapted to drive the same pixels 10R, 10G and 10B, formed on a drive panel 91. The pixels 10R, 10G and 10B are, for example, liquid crystal or organic EL elements adapted to emit red (R), green (G) and blue (B) light, respectively. Every three pixels, one 10R, one 10G and one 10B, form a pixel, and a display region 110 is made up of a plurality of pixels. Drive circuits such as a signal line drive circuit 120, scan line drive circuit 130 and pixel drive circuit 150, i.e., video display drivers, are disposed on the drive panel 91. An unshown sealing panel is attached to the drive panel 91, thus keeping the pixels 10R, 10G and 10B and the drive circuits sealed.

FIG. 12 is an equivalent circuit diagram of the pixel drive circuit 150. The same circuit 150 is an active drive circuit that includes transistors Tr1 and Tr2 to serve as one of the thin film transistors 1, 1A and 2. A capacitor Cs is provided between the transistors Tr1 and Tr2. The pixel 10R (or pixel 10G or 10B) is connected in series to the transistor Tr1 between a first power supply line (Vcc) and second power supply line (GND). In the pixel drive circuit 150 configured as described above, a plurality of signal lines 120A are arranged in the column direction, and a plurality of scan lines 130A are arranged in the row direction. Each of the signal lines 120A is connected to the signal line drive circuit 120 so that an image signal is supplied from the signal line drive circuit 120 to the source electrode of the transistor Tr2 via the signal line 120A. Each of the scan lines 130A is connected to the scan line drive circuit 130 so that a scan signal is supplied in sequence from the scan line drive circuit 130 to the gate electrode of the transistor Tr2 via the scan line 130A. In this display, each of the transistors Tr1 and Tr2 includes the thin film transistor 1, 1A or 2 according to one of the above embodiments, thus permitting high quality image display thanks to the thin film transistor 1, 1A or 2 offering excellent TFT characteristics. The display 90 configured as described above can be incorporated, for example, in pieces of electronic equipment described below in connection to application examples 2 to 6.

### Application Example 2

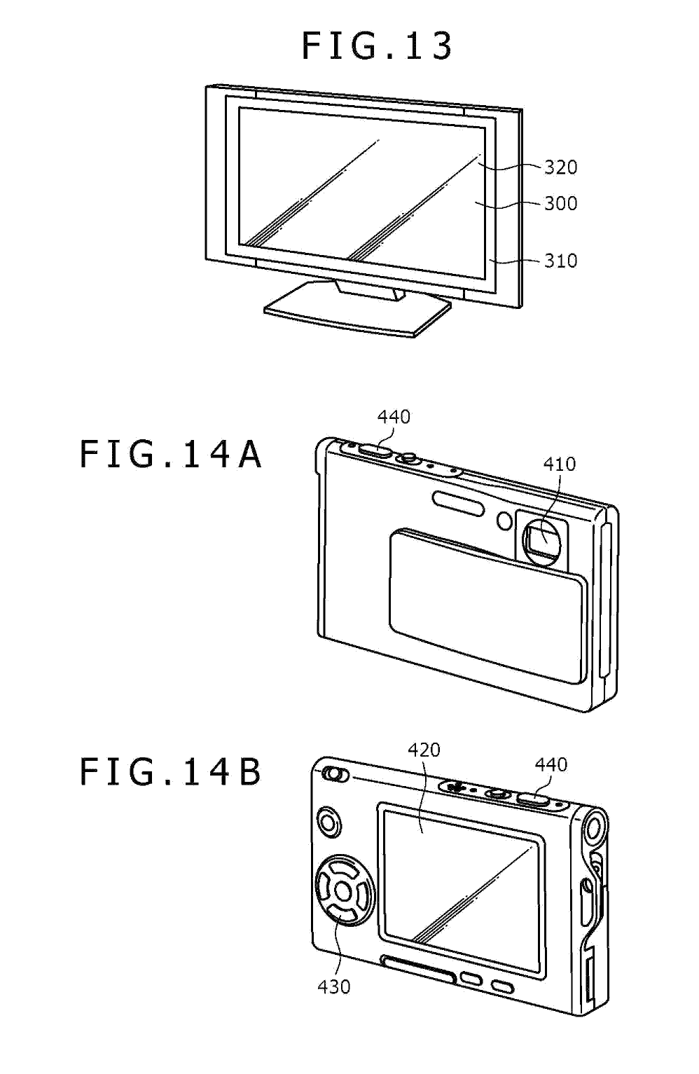

FIG. 13 illustrates the appearance of a television set. This television set has, for example, a video display screen section 300 that includes a front panel 310 and filter glass 320.

### Application Example 3

FIGS. 14A and 14B illustrate the appearance of a digital still camera. This digital still camera has, for example, a flash-emitting section 410, display section 420, menu switch 430 and shutter button 440.

### Application Example 4

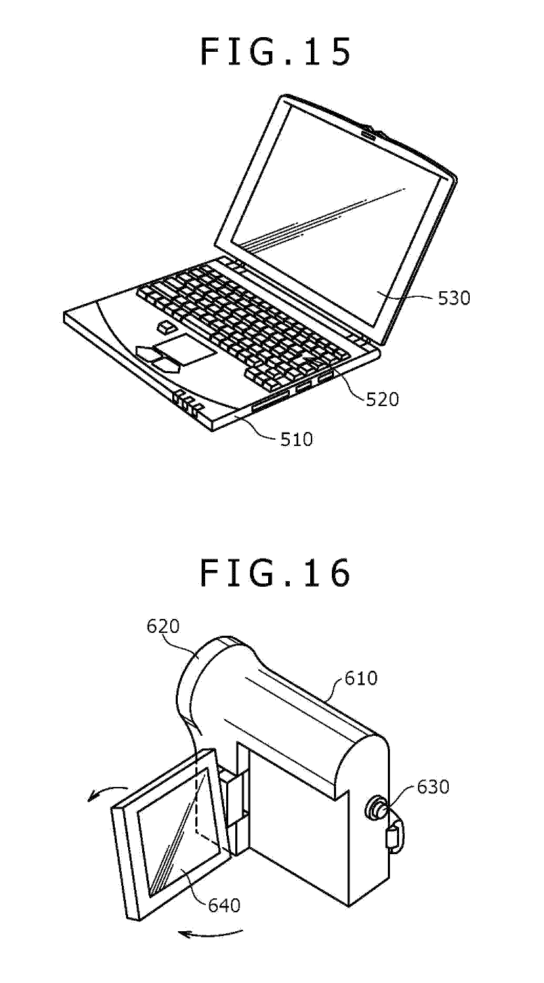

FIG. 15 illustrates the appearance of a laptop personal computer. This laptop personal computer has, for example, a main body 510, a keyboard 520 adapted to be manipulated for entry of text or other information and a display section 530 adapted to display an image.

### Application Example 5

FIG. 16 illustrates the appearance of a video camcorder. This video camcorder has, for example, a main body section 610, lens 620 provided on the front-facing side surface of the main body section 610 to capture the image of the subject, imaging start/stop switch 630 and display section 640.

### Application Example 6

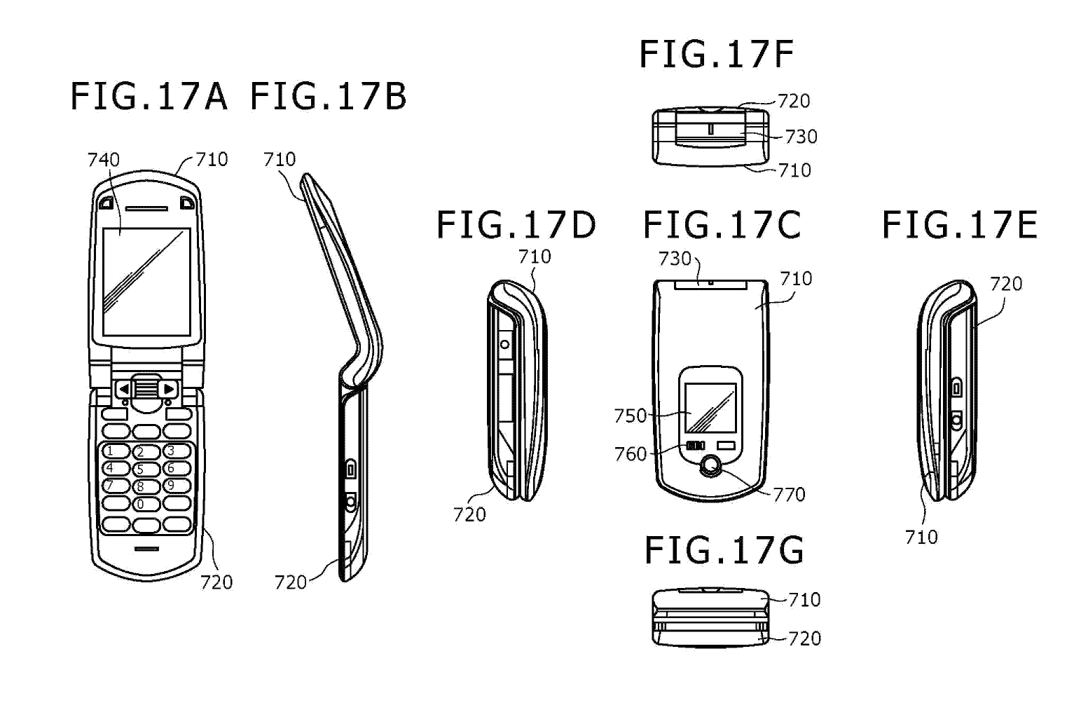

FIGS. 17A to 17G illustrate the appearance of a mobile phone. This mobile phone includes an upper enclosure 710 and lower enclosure 720 connected together by a connecting section (hinge section) 730 and has a display 740, subdisplay 750, picture light 760 and camera 770.

While described above by way of the preferred embodiments and modification example, the present disclosure is not limited to these embodiments and may be modified in various ways. For example, although a case has been described as an example in which the source/drain electrodes 15A and 15B each have a three-layer structure, the same electrodes 15A and 15B may each have a single layer structure. Alternatively, the same electrodes 15A and 15B may each have a multilayer structure made up of four or more layers.

On the other hand, for example, the materials and thicknesses of the layers and the film formation methods and conditions described in the preferred embodiments and other examples are not restrictive. Instead, the layers may be made of other materials and have different thicknesses and may be formed by other methods and under other conditions.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A manufacturing method of a thin film transistor comprising:
forming a channel layer made of an oxide semiconductor above a gate electrode with a gate insulating film provided therebetween, forming a channel protection film made of a conductive material adapted to cover the channel layer and forming a pair of source and drain electrodes in such a manner as to be in contact with the channel protection film; and
removing the region of the channel protection film between the source/drain electrodes by etching relying on selectivity between the conductive material and crystalline oxide semiconductor.

2. The manufacturing method of a thin film transistor of claim 1, wherein
the channel layer is formed by forming an amorphous oxide semiconductor film above the gate insulating film first and then transforming the amorphous oxide semiconductor into a crystalline oxide semiconductor prior to the formation of the source/drain electrodes.

3. The manufacturing method of a thin film transistor of claim 2, wherein
the source/drain electrodes are formed by forming a metal film in such a manner as to be in contact with the channel protection film first and then patterning the metal film, and
the amorphous oxide semiconductor is transformed into the crystalline oxide semiconductor prior to the formation of the metal film to form the channel layer.

4. The manufacturing method of a thin film transistor of claim 1, wherein
the channel layer is formed by forming a crystalline oxide semiconductor film above the gate insulating film.

5. The manufacturing method of a thin film transistor of claim 1, wherein
the source/drain electrodes are formed simultaneously with etching of the channel protection film.

6. The manufacturing method of a thin film transistor of claim 5, wherein
the source/drain electrodes each have a multilayer structure, and
the channel protection film serves also as one of the layers of the multilayer structure.

7. The manufacturing method of a thin film transistor of claim 1, wherein
the channel protection film is etched using the source/drain electrodes as an etching mask after the formation of the source/drain electrodes.

8. A manufacturing method of a thin film transistor comprising:
forming a channel layer made of an oxide semiconductor and a channel protection film made of a conductive material adapted to cover the channel layer;
removing the channel protection film by etching relying on selectivity between the conductive material and crystalline oxide semiconductor; and
forming a pair of source and drain electrodes above the channel layer in such a manner as to be in contact with the gate electrode and the channel layer with a gate insulating film provided therebetween.

9. A thin film transistor comprising:
a gate electrode;
a channel layer made of a crystalline oxide semiconductor and provided above the gate electrode with a gate insulating film provided therebetween;
a pair of channel protection films made of a conductive film, in contact with the channel layer and electrically disconnected from each other; and
a pair of source and drain electrodes each of which is electrically connected to the channel layer via one of the channel protection films.

10. The thin film transistor of claim 9, wherein
each of the opposed surfaces of the pair of source/drain electrodes forms the same surface with one of the opposed surfaces of the pair of channel protection films.

11. The thin film transistor of claim 9, wherein
edge portions of the pair of channel protection films are formed at the same positions as those of the channel layer.

12. The thin film transistor of claim 9, wherein
the pair of channel protection films are made of molybdenum (Mo), titanium (Ti), manganese (Mn) or copper (Cu), or an oxide, nitride or oxynitride thereof.

13. A display comprising:
a plurality of pixels; and
thin film transistors adapted to drive the plurality of pixels, wherein
each of the thin film transistors includes
a gate electrode,
a channel layer made of a crystalline oxide semiconductor and provided above the gate electrode with a gate insulating film provided therebetween,
a pair of channel protection films made of a conductive film, in contact with the channel layer and electrically disconnected from each other, and
a pair of source and drain electrodes each of which is electrically connected to the channel layer via one of the channel protection films.
